(19) United States
(12) Patent Application Publication
(10) Pub. No.: US 2020/0203554 A1
(43) Pub. Date: Jun. 25, 2020

(54) INLINE SOLAR CELL LAMINATION

(71) Applicant: MiaSolé Hi-Tech Corp., Santa Clara, CA (US)

(72) Inventors: Marcelle S. Marshall, Campbell, CA (US); Nicholas A. Franzino, San Jose, CA (US)

(21) Appl. No.: 16/227,120

(22) Filed: Dec. 20, 2018

(51) Int. Cl. H01L 31/18; B32B 37/00; B32B 37/10; H02S 50/10

(52) U.S. Cl. CPC H01L 31/1876; B32B 37/0053; H02S 50/10; B32B 37/1018; H01L 31/1868

(57) ABSTRACT

Provided herein are lamination apparatuses and processes for inline lamination of solar cells. In some embodiments, the apparatus includes a roller having a core and a compliant sleeve, such as a silicone sleeve, annularly surrounding the core. A release layer may be provided in the form of an annular outermost coating of the roller or as a belt. In some embodiments, the release layer is a fiberglass coated with a fluoropolymer. The core/compliant sleeve/release layer comes in direct contact with a wire assembly to be laminated on the front side of the cell. The compliant sleeve forces the polymer of the wire assembly to conform between the wire, reducing void space between the solar cell and wire assemblies. Also provided are thin film solar cells having reduced cavity and tent areas and widths.

### BACKGROUND

Photovoltaic cells are widely used for the generation of electricity. Multiple photovoltaic cells may be interconnected in module assemblies. Such modules may in turn be arranged in arrays and integrated into building structures or otherwise assembled to convert solar energy into electricity by the photovoltaic effect. Certain photovoltaic cell fabrication processes involve depositing thin film materials on a substrate to form a light absorbing layer sandwiched between electrical contact layers. The front or top contact is a transparent and conductive layer for current collection and light enhancement, the light absorbing layer is a semiconductor material, and the back contact is a conductive layer to provide electrical current throughout the cell.

### SUMMARY

Provided herein are lamination apparatuses and processes for inline lamination of solar cells. In some embodiments, the apparatus includes a roller having a core and a compliant material, such as a silicone sleeve, surrounding the core. The compliant material may annularly surround the core as a sleeve or be provided in the form of a belt. A release layer may be provided in the form of an annular outermost coating of the roller or as a belt. In some embodiments, the release layer is a fiberglass coated with a fluoropolymer. The core/compliant sleeve/release layer comes in direct contact with a wire assembly to be laminated on the front side of the cell. The compliant sleeve forces the polymer of the wire assembly to conform between the wire, reducing void space between the solar cell and wire assemblies. Also provided are thin film solar cells having reduced cavity areas and widths.

In some embodiments, a lamination apparatus for laminating a lamination stack is provided. The apparatus includes a roller having a core and a compliant material surrounding the core, the compliant material characterized by having a pressure to compress 25% of between 1 and 30 psi; and a release layer configured to directly contact the lamination stack. In some embodiments, the compliant material comprises silicone. In some embodiments, the release layer comprises woven fiberglass. In some such embodiments, the fiberglass is coated with a fluoropolymer. In some embodiments, thickness of the compliant material is between 0.4 mm and 40 mm. In some embodiments, the thickness of the release layer is between 0.08 mm and 0.4 mm. In some embodiments, the compliant material is a sleeve that annularly surrounds the core. In some such embodiments, the release layer annularly surrounds the sleeve. In some embodiments, the release layer is in the form of a belt. In some embodiments, the compliant material is in the form of a belt. In some embodiments, the apparatus further includes a hot air jet configured to heat part of the lamination stack before it reaches the roller.

Also provided herein are solar cell manufacturing lines that include a lamination apparatus as described above. In some embodiments, the solar cell manufacturing lines also include a solar cell material station to coat or otherwise form photovoltaic stacks on a substrate. In some embodiments, the solar cell manufacturing lines include a cutting station to form cells. In some embodiments, the manufacturing line includes a solar cell testing station to measure cell efficiency of the laminated solar cells.

Also provided herein are methods of laminating solar cells. The methods include providing a lamination apparatus comprising a first roller and a second roller, the first roller comprising a core and a compliant material surrounding the core; feeding a lamination stack including thin film solar cell and a wire assembly in between the first roller and the second roller, the wire assembly comprising a wire and one or more polymer layers, such that the wire assembly is between the thin film solar cell and the first roller; and compressing the lamination stack between the first roller and the second roller to laminate the wire assembly to the thin film solar cell. In some embodiments, the methods include heating the wire assembly prior to feeding it in between the first roller and second roller. In some embodiments, the methods include heating the backside of the solar cell prior to feeding it in between the first roller and the second roller. In some embodiments, the methods include compressing the lamination stack comprises directly contacting the wire assembly with a release layer that is in contact with the compliant sleeve. In some embodiments, the release layer annularly surrounds the compliant sleeve. In some embodiments, the release layer is configured as a belt. In some embodiments, the method includes comprising transferring a texture of the release layer to the wire assembly. In some embodiments, the solar cell is a CIGS solar cell. In some embodiments, the wire assembly comprises multiple wire segments having a pitch between 4 mm and 10 mm. In some embodiments, the wire has a diameter between 0.06 and 0.1 mm. In some embodiments, the methods further include testing the efficiency of the laminated solar cell immediately after lamination.

Also provided herein are laminated solar cells that include a solar cell stack, a wire, and a polymer wire carrier overlying the wire and laminated to the solar cell stack. The laminate solar cells may be characterized by a maximum average tent area and/or cavity width.

These and other features are described further below with reference to the drawings.

### BRIEF DESCRIPTION OF DRAWINGS

FIG. 1 shows front and back views of a strip of a wire assembly configured to be laminated to a solar cell.

FIG. 2 shows a perspective view of cell-width strips of an example of a thin film solar cell stack.

FIG. 3A depicts a cross-sectional view of a wire assembly including a wire and wire carrier along line 1-1 of FIG. 1.

FIG. 3B depicts a cross-sectional view of a wire assembly along line 2-2 of FIG. 1.

FIG. 4 shows a schematic of a roller for a lamination apparatus including a compliant sleeve and release layer.

FIG. 5 shows a schematic of a portion of release layer including woven strands of fiberglass.

FIG. 6 is a block diagram showing various elements of an example of a solar cell manufacturing system including inline lamination.

FIG. 7 is a schematic derived from a cross-sectional image of a laminated solar cell.

FIGS. 8A and 8B show plots of tent areas and cavity widths for samples laminated with a conventional roller and a compliant sleeve roller as described herein.

FIGS. 9A and 9B show schematic examples of lamination apparatuses.

FIG. 10 shows an example of a lamination stack for a vacuum lamination apparatus.

### DETAILED DESCRIPTION

Reference will now be made in detail to specific embodiments of the invention. Examples of the specific embodiments are illustrated in the accompanying drawings. While the invention will be described in conjunction with these specific embodiments, it will be understood that it is not intended to limit the invention to such specific embodiments. On the contrary, it is intended to cover alternatives, modifications, and equivalents as may be included within the spirit and scope of the invention. In the following description, numerous specific details are set forth in order to provide a thorough understanding of the present invention. The present invention may be practiced without some or all of these specific details. In other instances, well known mechanical apparatuses and/or process operations have not been described in detail in order not to unnecessarily obscure the present invention.

While most of the description below is presented in terms of systems, methods and apparatuses related to solar cells, the invention is by no means so limited. For example, the invention covers inline lamination of any work piece. The work piece may be of various shapes, sizes, and materials. In the following description, numerous specific details are set forth in order to provide a thorough understanding of the present invention. It will be apparent, however, that the present invention may be practiced without limitation to some of the specific details presented herein.

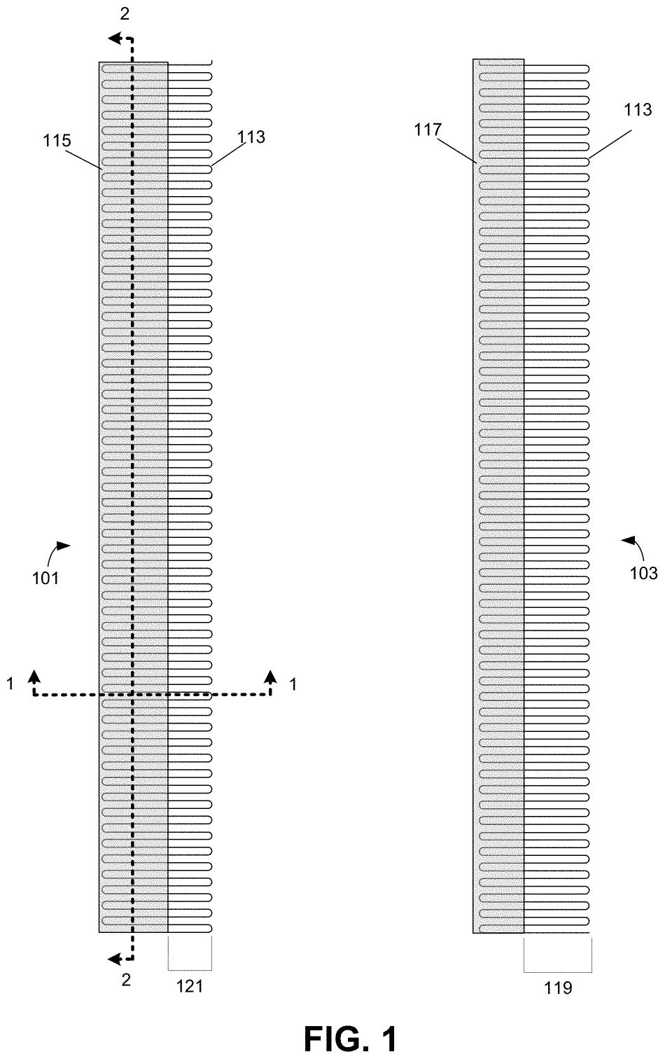

Embodiments of the present invention relate to lamination of photovoltaic cells (also referred to as solar cells). FIG. 1 shows a front view 101 and a back view 103 of a strip of a wire assembly including a wire 113 and front and back wire carriers 115 and 117, respectively. The front view 101 shows the wire 113 and the front wire carrier 115, which overlies a portion of the wire 113. For clarity, the back wire carrier 117 is not depicted in the front view 101. An exposed portion 121 of the wire 113 is configured to interconnect photovoltaic cells. The back view 503 shows the wire 113 and the back wire carrier 117, which overlies a portion of the wire 113. An exposed portion 119 of the wire 113 is configured to contact the top layer of a cell (e.g., a TCO layer) and act as a current collector.

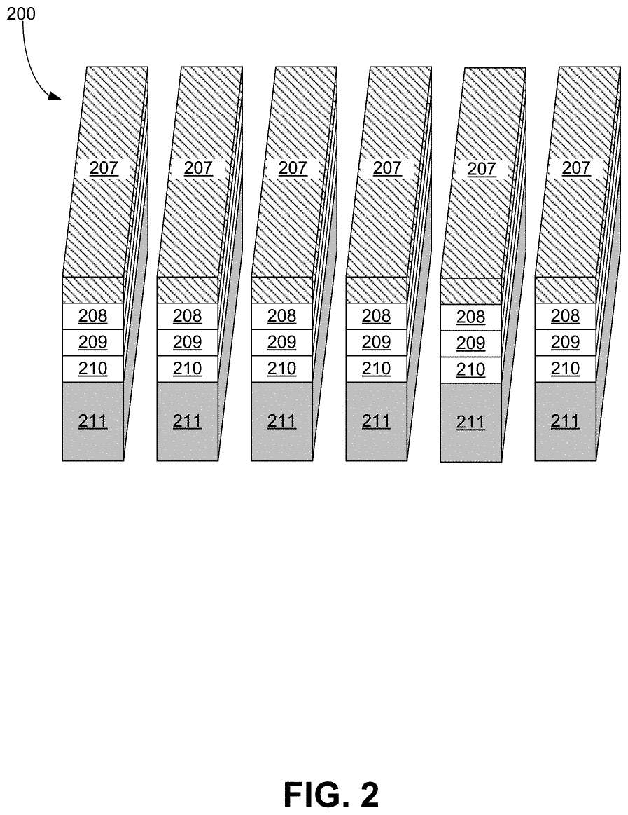

An example of a thin film solar cell stack is depicted in FIG. 2, which shows a perspective view of cell-width strips 200 of thin film solar cell stacks. Substrate 211 supports thin films 210, 209, 208 and 207. Layers 208 and 209 form a p-n junction, with a p-type semiconductor layer 209 deposited on a back electrical contact layer 210 and an n-type semiconductor layer 208 deposited on p-type semiconductor layer 209 to complete a p-n junction. According to various embodiments, any suitable semiconductor material such as CIGS (copper indium gallium selenide), CIS (copper indium selenide), CdTe, CdS, ZnS, ZnO, amorphous silicon, polycrystalline silicon, etc. are used for layers 208 and 209. For example, the p-type semiconductor layer 209 is CIGS or CIS, and the n-type semiconductor layer 208 is CdS or a cadmium free material, such as ZnS, ZnO, etc. Top electrode layer 207 overlays the p-n junction. Top electrode layer 207 is transparent, allowing light to reach light absorbing layer 209. In certain embodiments, top electrode layer 207 is a transparent conducting oxide (TCO), for example, zinc oxide, aluminum-doped zinc oxide (AZO), indium tin oxide (ITO), and gallium doped zinc oxide. Back electrical contact layer 210 provides electrical contact to allow electrical current to flow through the solar cell, and may be made of any appropriate material, e.g., molybdenum, niobium, copper, silver, etc. As indicated above, in certain embodiments, substrate 211 is a metallic substrate, e.g., a thin stainless steel foil, though it may also be other metals including, but not limited to, titanium, copper, aluminum, beryllium, and the like. The substrate 211 may be relatively thin, less than or equal to about 2 to 10 mils (a mil is a thousandth of an inch, i.e., 1/1000 inch) in some instances, though other suitable thicknesses may also be used. In many cases the substrate is thin enough to be flexible. As indicated, the stacks 200 shown in FIG. 2 are long cell-width strips, which may be cut further to define individual cells as shown in FIG. 1. The thin film solar cells stacks shown in FIG. 2 are provided for context and not intended to be limiting. For example, the wire current collectors and/or interconnects described herein may be used with other types of solar cells as well as in other fields.

Returning to FIG. 1, as described above, the wire assembly includes wire 113 and wire carriers 115 and 117, which are also referred to as decals. In FIG. 1, wire 113 is in a serpentine pattern, though other patterns are within the devices and processes described herein. For example, the wire may be configured in a pattern that spans a length of a decal and traverses an edge of the decal along the length of the decal. As used herein, the term “serpentine” refers to a form having substantially uniformly spaced, substantially co-extensive and substantially parallel lengths of wire connected via substantially rounded end portions. In the depicted embodiment, the wire 113 is configured as a current collector to collect current generated by the solar cell and as a solar cell interconnect to electrically connect the cell to another cell, for example, in a solar module. In other solar cell or module configurations, the wire may be configured only as a current collector or only as an interconnect.

Referring again to front view 101, a portion 119 of wire 113 is configured to overlay a conductive transparent top layer of the solar cell, and collect current generated from the cell. The wire 113 is typically a thin, highly conductive metal wire. Examples of wire metals include copper, aluminum, nickel, chrome, or alloys thereof. In some embodiments, a nickel coated copper wire is used. The wire maintains its serpentine or other form without significant material strain. In certain embodiments, the wire is 24 to 56 gauge, or in particular embodiments, 32 to 56 gauge, for example 40 to 50 gauge. In specific embodiments, the wire has a gauge of 34, 36, 40, 42, 44, or 46. In some examples, the wire diameter is between about 0.06 and 0.10 mm, e.g., 0.08 mm. Larger or smaller wires may also be used according to various embodiments, for example, from 1 micron-1 mm diameter. Front decal 115 overlays all or part of portion 119. (Back decal 117, which overlies portion 121 of wire 113, is not shown in this view for clarity). Front decal 115 is a transparent, insulating carrier for the conductive wire. Examples of decal materials include thermoplastic materials such as polyethylene terephthalate (PET), ionomer resins (e.g., poly(ethylene-co-methacrylic acid), commercially available as Surlyn™, E. I. du Pont de Nemours and Company), polyamide, polyetheretherketone (PEEK), or combinations of these.

The wire 113 is significantly more conductive than the conductive transparent top layer and so improves current collection. The pitch of the wire, as measured by the distance between the centers of adjacent end portions, determines the distance current travels through the transparent conducting oxide prior to reaching the highly conductive wire, with the maximum distance current has to travel through the transparent conductive oxide is ¼ pitch. Reducing the pitch increases current collection. It also decreases the useful surface area of the cell, however, by covering the light absorbing layer. In certain embodiments, the pitch is between about 4 and 10 mm, e.g., about 6.5 mm, though other distances may also be used, as appropriate. The relatively small pitches can make it difficult to conform the decal around the wires of the solar cell using conventional atmospheric pressure laminators.

Returning to FIG. 1, view 103 depicts metallic substrate 111 and interconnect portion 121 of serpentine wire 113. Back decal 117, which overlies portion 121 of serpentine wire 113 as shown in view 103, is an insulating carrier for serpentine wire 113. In view 103, the conductive side of interconnect portion 121 faces down, able to make contact with a metallic substrate of an adjacent cell.

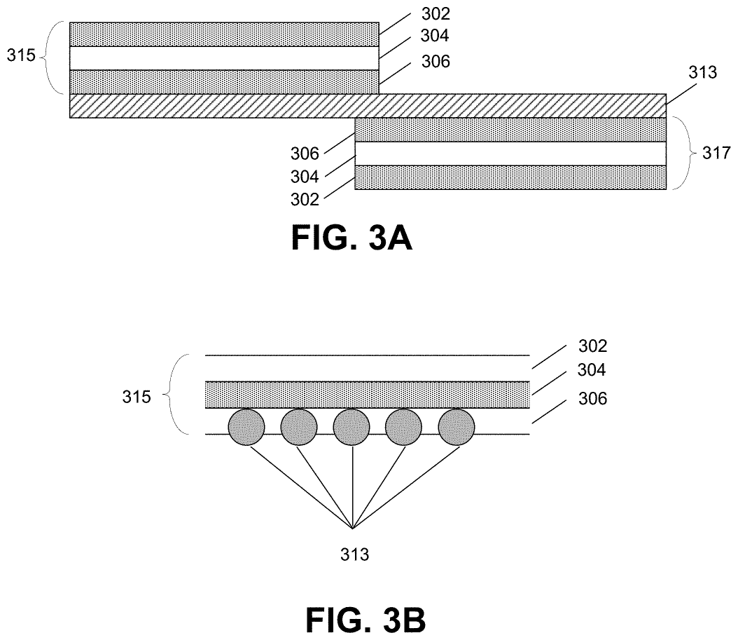

As described further below, apparatuses and methods of inline lamination of solar cells are provided herein. In some embodiments, a wire assembly is laminated with a solar cell as described in FIG. 2 to form a laminated thin film solar cell as described in FIG. 1. Further description of examples of wire assemblies is provided below with reference to FIGS. 3A and 3B.

FIG. 3A depicts a cross-sectional view of a wire assembly including a wire and wire carrier (or decal) along line 1-1 of FIG. 1, according to certain embodiments. The wire assembly includes the top carrier strip 315, a bottom carrier strip 317, and a wire 313. In the example embodiment, the top strip 315 and the bottom strip 317 each include three polymer films: a first polymer film 302, a second polymer film 304, and a third polymer film 306. In some embodiments, the first polymer film contacts the second polymer film and the second polymer film contacts the third polymer film. In other embodiments, there is a layer of adhesive between the first polymer film and the second polymer film. In further embodiments, there is a layer of adhesive between the second polymer film and the third polymer film. Note that FIG. 3A is a schematic representation of a wire assembly, and that in some embodiments, the wire 313 is embedded in the third polymer film of the top strip and/or the bottom strip. In the depicted embodiment, the top strip 315 and the bottom strip 317 include the same polymers arranged in the same order (the innermost polymer layer being the third polymer film 306, etc., but in other embodiments, the top strip and the bottom strip have different polymer film stacks. Further, in some embodiments, one or both of the top strip and the bottom strip does not include first polymer 302. In FIG. 3A, the top strip 315 and bottom strip 317 overlap in a lateral direction. In different embodiments, the amount of this overlap is variable, and in some embodiments, the top strip 315 and the bottom strip 317 do not overlap. The dimensions of the top strip (i.e., the thicknesses and widths of the first polymer film, the second polymer film, and the third polymer film) and the bottom strip are the same in some embodiments, and different in other embodiments.

FIG. 3B depicts a cross-sectional view of a wire assembly along line 2-2 of FIG. 1, according to certain embodiments. FIG. 3B shows the wire 313 embedded in third polymer film 306 of the top strip 315. The top strip 315 also includes first polymer film 302 and second polymer film 304. A surface of the wire facing away from second polymer film 304 is exposed. In some embodiments, the exposed surface of the wire makes electrical contact with a layer of material underlying the third polymer film, such as a transparent conducting oxide layer.

In certain embodiments, the polymer films 302, 304, and 306 are thermoplastic polymer films. For example, the polymer films may be thermoplastic polymer films such as polyethylene terephthalate (PET) films, poly(methyl methacrylate) (PMMA) films, fluorinated ethylene propylene (FEP) films, ethylene tetrafluoroethylene (ETFE) films, polycarbonate films, polyamide films, polyetheretherketone films (PEEK) films, low density polyethylene films, low density urethane films, or low density polymer (with ionomer functionality) films (e.g., poly(ethylene-co-methacrylic acid) (Surlyn™)). In some embodiments, the second polymer film is a polyethylene terephthalate (PET) film, a poly(methyl methacrylate) (PMMA) film, a fluorinated ethylene propylene (FEP) film, an ethylene tetrafluoroethylene (ETFE) film, or a polycarbonate film. The first polymer film and the third polymer film are the same type of polymer film in some embodiments, and in other embodiments, they are different types of polymer film. In some embodiments, the first and the third polymer films are a low density polyethylene film, a low density urethane film, or a low density polymer (with ionomer functionality) film. In a specific embodiment, the first and the third polymer films are films of poly(ethylene-co-methacrylic acid) (Surlyn™).

In some embodiments, the first, second, and third polymer films are thermoplastic polymer films, with the melting point temperature of the second thermoplastic polymer film being greater than the melting point temperatures of the first and the third polymer films.

In some embodiments, the wire is in contact with the second polymer film, as depicted in FIG. 3B; in other embodiments, the wire is not in contact with the second polymer film. In some embodiments there is a layer of adhesive between the poly(ethylene-co-methacrylic acid) film and the polyethylene terephthalate film. In some embodiments the layer of adhesive is a layer of polyurethane adhesive. In some embodiments the thickness of the layer of adhesive is about 0.5 microns to 10 microns.

In other embodiments the first polymer film and/or the third polymer film are an adhesive material. In other embodiments a non-polymeric adhesive material is used in place of the first polymer film and/or the third polymer film.

In certain embodiments, at least the top polymer film (polymer film 302 in FIG. 3A) is an adhesive material. If present, the bottom polymer film (polymer film 304 in FIG. 3B) may or may not be an adhesive material according to various embodiments. In some embodiments, it may be an adhesive to facilitate holding wire 313.

An adhesive material is a material that will flow around module components under application of an energy (e.g., heat, pressure, UV radiation) and then set once the energy is removed. The adhesives in the modules herein are also optically transparent and thermally stable over the operating temperature of the module.

In some of these embodiments, the adhesive material is a silicone-based polymer. Some examples of such adhesive materials include the following materials available from Dow Corning in Midland, Mich.: two part translucent heat cure adhesive (part number SE1700), and two part fast cure low modulus adhesive (part numbers JCR6115 and JCR 6140). In some embodiments the adhesive material is a thermoset polymer material. Examples of such adhesive materials include polyurethanes, epoxies, silicones, acrylics and/or combinations of these materials. A further example of such an adhesive material is a reactively functionalized polyolefin (e.g., with functional acrylate groups). In further embodiments the adhesive material has pressure sensitive adhesive (PSA) characteristics and may be cross-linked with ultra-violet light, an electron beam, or thermal energy. A PSA may be a non-Newtonian PSA or thixotropic PSA. It may include one or more of the following materials: a UV-reactive styrenic block copolymer, a cationic curing epoxy-functional liquid rubber, a saturated polyacrylate, an acrylate monomer, and an acrylate oligomer, and an acrylated polyester. In some embodiments, the first polymer film and the third polymer film each have a thickness of no more than about 25 microns (or 1 mil).

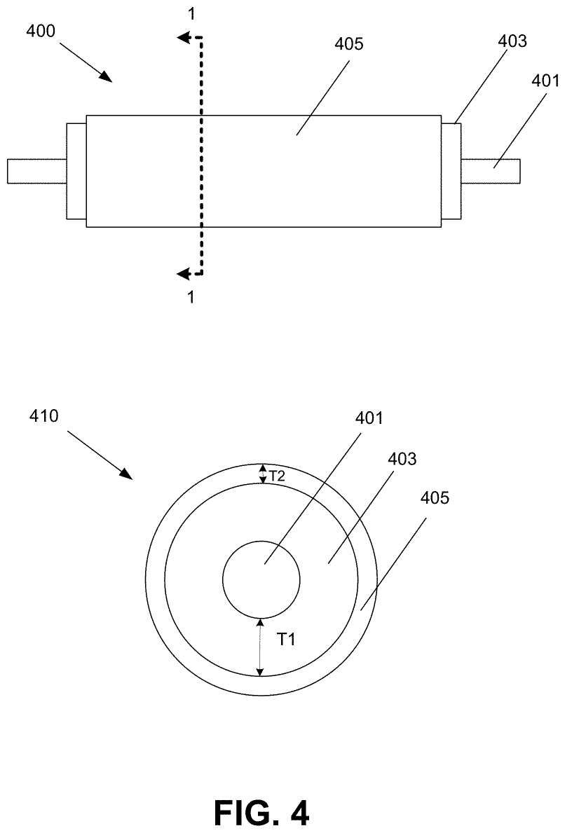

According to various embodiments, when laminating a wire assembly with a solar cell to form a laminated solar cell, a wire assembly, including one or more polymer layers and the wire, is laminated with the solar cell in an inline lamination apparatus as described herein. FIG. 4 shows a schematic of a roller 400 that includes a core 401, a compliant sleeve 403, and a release layer 405. The compliant sleeve 403 is a compliant material such as silicone foam or thread. The use of a compliant material allows the sleeve to better penetrate into the small areas between wire segments, reducing void space caused by tenting and reducing defects. The release layer 405 includes a material such as Teflon® that provides a non-stick interface between the compliant sleeve 403 and the lamination stack. At 410, a cross-section along line 1-1 is shown.

The compliant sleeve is a material that can conform around the wires of the wire assembly. In some embodiments, the compliant sleeve is characterized by a pressure to compress 25% of 1 to 30 psi, e.g., 1 to 10 psi, or 1 to 5 psi. It also is thermally stable at the temperature of lamination. Lamination temperature depends on the adhesive used; according to various embodiments, the compliant sleeve is thermally stable between −20° C. and 200° C., or from 60° C. to 100° C. in some embodiments. One example is silicone, which may be provided in any appropriate form. For example, the compliant sleeve may be a silicone foam or a roll of silicone thread. Other materials that remain chemically stable and elastic at the operating temperature of the laminator may also be used. The thickness of the compliant sleeve will depend on the topography of the laminated material. In some embodiments, the thickness (T1 in FIG. 4) is between 5-500 times the height of the laminated topography. Example thicknesses may be between 0.1 and 2 inches. For an 80 micron diameter wire, a compliant sleeve thickness may be between 0.4 and 40 mm (0.016 and 1.6 inches).

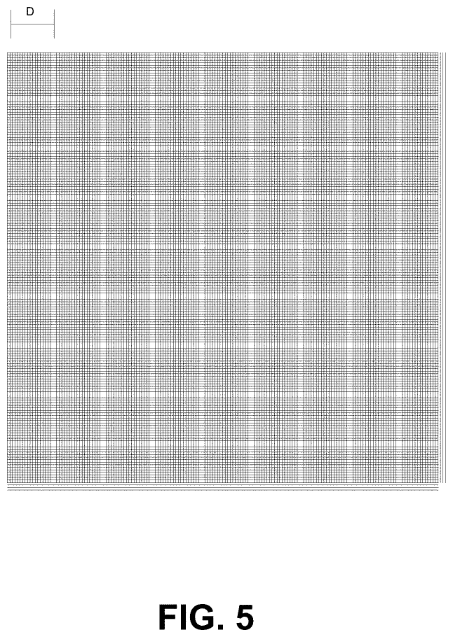

The release layer may be Teflon® or other polytetrafluoroethylene (PTFE) coated. In some embodiments, the release layer is woven PTFE-coated fiberglass. The release layer has high resistance to abrasion and tearing. The release layer may also be any appropriate thin material coated with PTFE or other release material. In some embodiments, interlaced fiberglass or other strands is beneficial as the texture may be transferred to the interconnect wire surface during the lamination process. This reduces reflectance of the wire and can improve cell performance. FIG. 5 shows a schematic of a portion of release layer including woven strands of fiberglass—bundles of multiple strands of fiberglass are woven together. In an example, each bundle may be about 50-5000 microns wide (D in FIG. 5).

Examples thicknesses for the release layer (T2 in FIG. 4) range from 3-16 mils or 0.08-0.4 mm. The release layer is thin and flexible while maintaining thermal and mechanical stability. In some embodiments, the release layer is characterized as having a breaking strength of at least 40 lb/in in the warp direction and fill direction.

In some embodiments, a release layer may not be necessary. For example, if the layer of lamination stack that is to interface with the lamination apparatus (layer 302 in the example of FIG. 3A) is not an adhesive layer, the lamination apparatus may include a compliant sleeve as described above with no release layer.

The core is generally any thermally stable material that does not appreciably compress under pressures of 1-30 psi. In operation, the roller including the compliant sleeve and, if present, release layer comes presses against a wire assembly to be laminated on the front side of the cell such that the release layer, or if not present, the compliant sleeve directly contacts the wire assembly. The wire assembly, including decal and wire interconnect, may be provided in a roll for continuous lamination in some embodiments.

According to various embodiments, one or more heat sources may be present to laminate. For example, the backside of the cell may be pressed against a heated plate or roller to allow the wire assembly to be laminated on the front side of the cell. In another example, hot air may be directed at the wire assembly immediately before it is rolled onto the solar cell. Hot air may also be directed at the bottom of the solar cell immediately before it is placed into contact with the wire assembly.

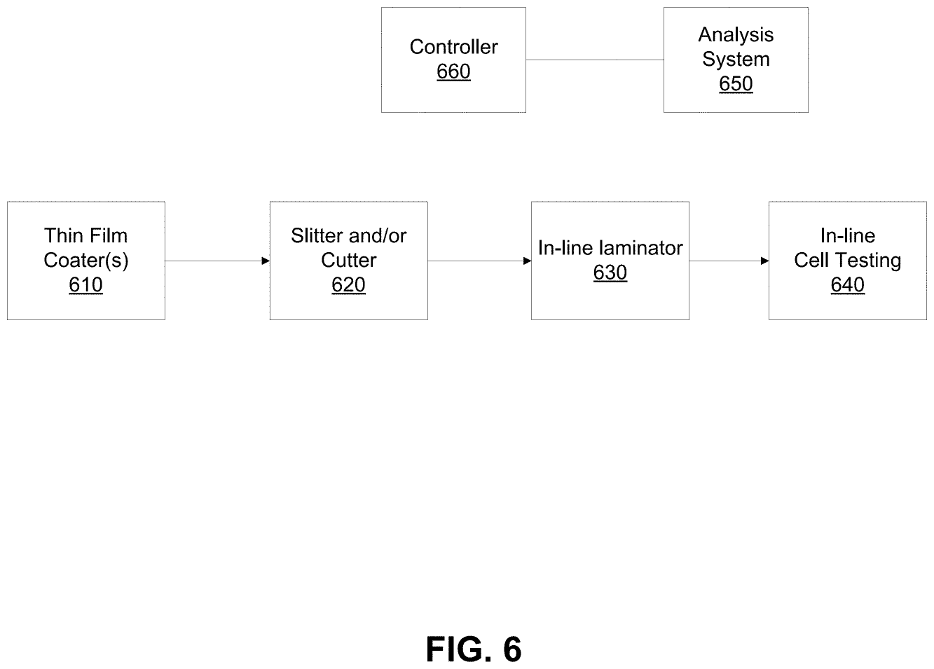

In some embodiments, the lamination process described herein is provided as a part of a cell manufacturing process. FIG. 6 is a block diagram showing various elements of an example of a solar cell manufacturing system including inline lamination. At 610 is a thin film deposition coater or coaters, in which thin film materials, which may include light absorbing materials as well as back and top contact layers, are deposited or otherwise coated on a substrate. The substrate may be provided as a web, such as a stainless steel web.

After deposition, the substrate having thin films deposited thereon is transferred to cutter and/or slitter 620 where it may be cut in a variety of manners to define cells. For example, a web may first be slit in a first direction to form long strips of thin film photovoltaic stacks, which are then cut as appropriate into solar cells.

The solar cells are then transferred to an inline laminator 630 as described above for inline lamination with the wire assembly, which may be provided as a roll including wire interconnects and decals. The wire interconnects and decals may have been previously laminated together to form the wire assembly, though the individual components could be laminated in the inline lamination apparatus.

Once laminated, the cells may be tested at one or more cell testing stations 640. Testing may include measurements of one or more of efficiency, conductivity, or other appropriate metrics. Inline testing has several advantages including the ability to detect performance issues or the presence of defects. In some embodiments, a controller 660 may control all or some aspects of the manufacturing process. An analysis system 650 may be configured to receive signals from the inline cell testing apparatus. In some embodiments, the controller 660 may halt or alter certain operations of the manufacturing process based on an analysis. For example, if the tested cells do not meet conductivity or other requirements, the process may be halted.

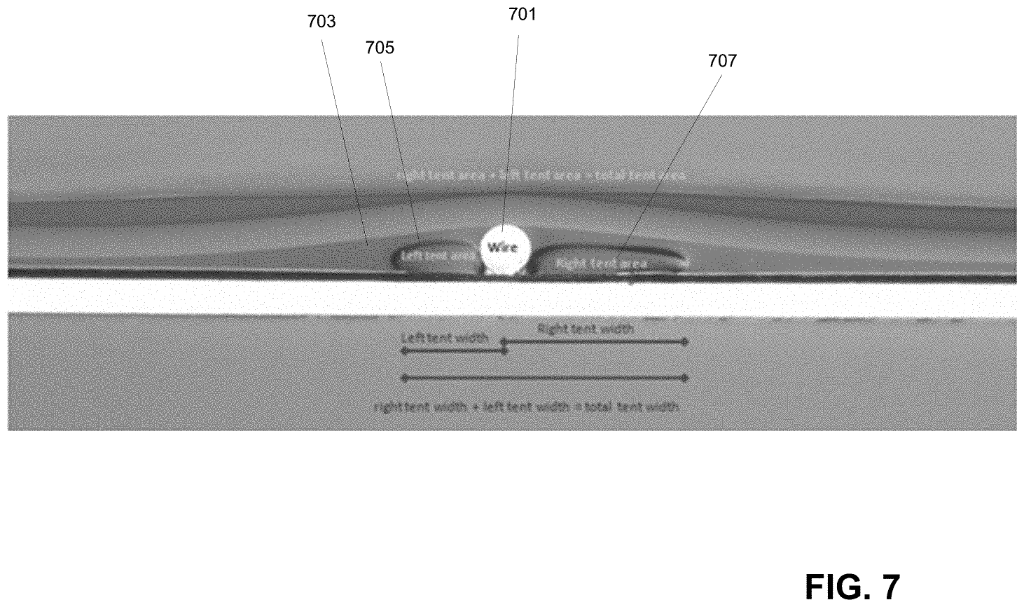

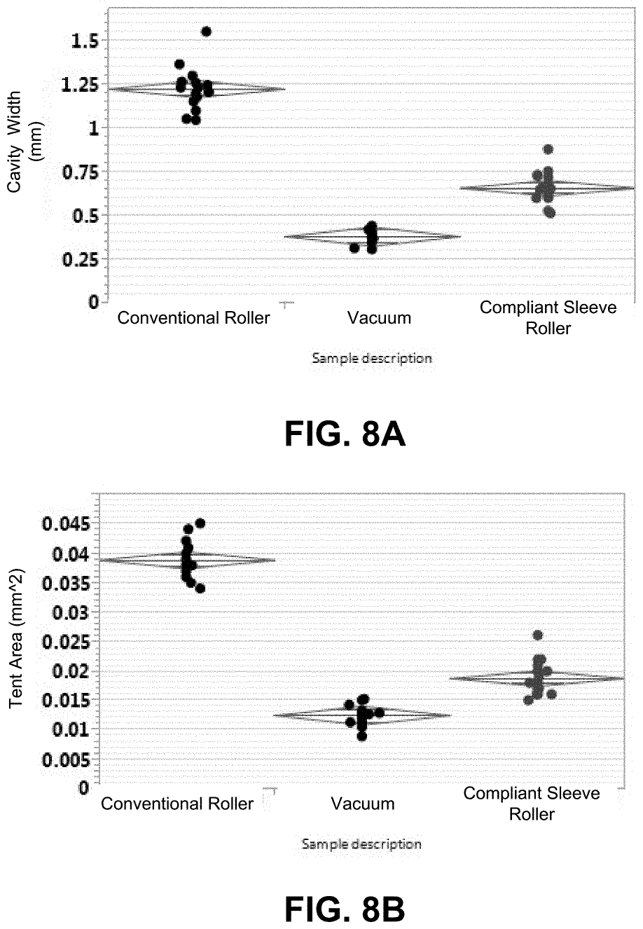

Inline laminated solar cells may be characterized as described below with reference to FIGS. 7 and 8. First in FIG. 7, a schematic derived from a cross-sectional image of a laminated solar cell is shown. The laminated solar cell includes wire 701, which contacts the thin film solar cell stack, and decal material 703. Void spaces, also referred to as tent areas, are present on the left and right sides of the wire 701.

An inline laminated solar cell can be characterized by total area of the cavity in the laminate surrounding a segment of the wire, including the wire area, measured as a cross-section of the solar cell that is perpendicular to the wire. In addition or as an alternative, an inline laminated solar cell can be characterized by total width of the cavity in the laminate surrounding a segment of the wire, including the wire width. The tent area and tent widths may also be characterized without the wire area and wire width by subtracting the known wire area or width as appropriate.

Total cavity area=Left tent area+right tent area+wire area

Total cavity width=Left tent width+right tent width including wire

Total tent area=Left tent area+right tent area

Total tent width=Left tent width+right tent width

The table below shows average cavity widths and areas for lamination by a hard roller and lamination by a roller including a silicon compliant sleeve and a PTFE coated fiberglass release layer as described above. The wire size for both laminations was 0.08 mm.

| | Average Tent Area | Average |
|---|---|---|
| Roller | (left tent area + right tent area) | Cavity width |
| Hard roller | .039 mm² | 1.25 mm |
| Roller with compliant | .019 mm² | 0.66 mm |
| sleeve and release layer | | |

The average was found by measuring cavity widths and tent areas at multiple positions of a wire. The reduction in cavity size shows that the lamination apparatus as described above results in greater conformality of the lamination around the wire. It is expected that cavity size of 0.12 mm² tent area and 0.37 mm total width can be achieved using the processes as described above. The reduction in cavity size also reduces cell degradation. FIGS. 8A and 8B show plots of tent areas and cavity widths for samples laminated with a conventional roller and a compliant sleeve roller as described herein. For comparison, data was collected for vacuum laminated samples. Lamination by compliant sleeve roller is comparable to vacuum lamination. Unlike vacuum lamination, it can be used in an inline process.

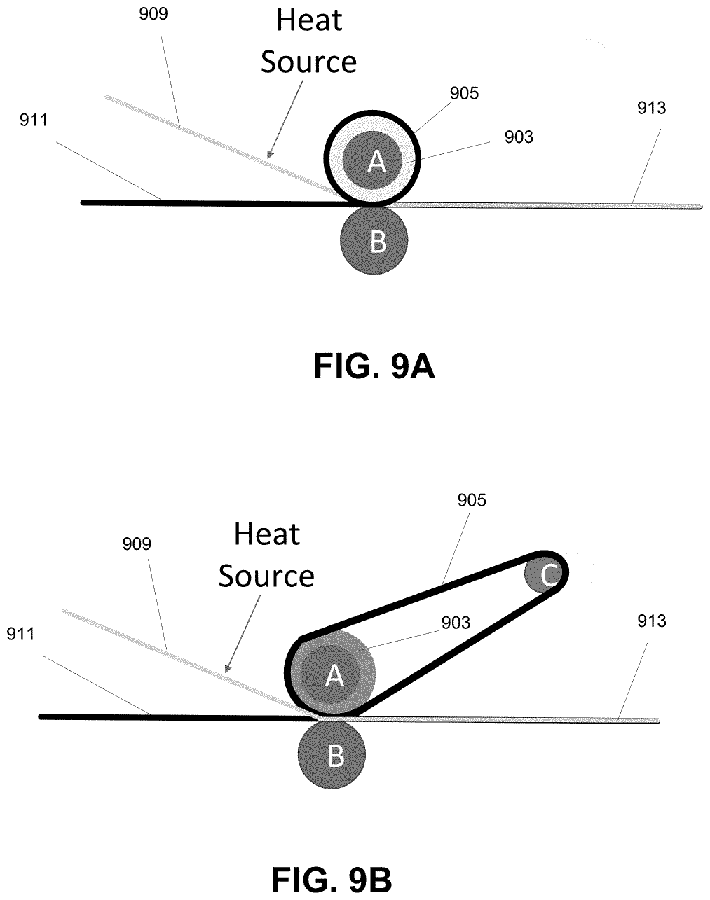

FIGS. 9A and 9B show schematic examples of lamination apparatuses. First, in FIG. 9A, a roller A including a compliant sleeve 903 and release layer 905 are shown. A roller B supports the backside of the solar cell 911 and wire assembly 909 and guides it through the lamination. A heat source (such as jet of hot air) may heat the wire assembly 909 before it reaches the rollers. Exiting the lamination apparatus is a laminated solar cell 913. The process generally occurs at atmospheric pressure.

According to various embodiments, one or both of the compliant material and release layer may be provided as a belt. FIG. 9B shows an example of a lamination apparatus including a roller A including a compliant sleeve 903. A release layer 905 as described above is provided as belt guided by roller C. The release layer may be a Teflon®-coated fiberglass or any other appropriate release layer as discussed above. Still in other embodiments, a compliant material optionally coated with a release layer may be provided as a belt.

Also provided herein are cells laminated with an inline lamination apparatus as described above or a vacuum lamination process. Cell vacuum lamination can used to simulate the lamination process solar cells undergo during module build. Cell lamination improves adhesion to solar cell stack thereby, as demonstrated above with respect to FIGS. 8A and 8B, reducing tenting around the wire. A solar cell having a wire interconnect, and laminated wire carrier with an average cavity width of less than 1 mm, or less than 0.75 mm, or less than 0.5 mm may be provided herein. A solar cell having a wire interconnect, and laminated wire carrier with an average tent area of less than 0.025 mm², or less than 0.02 mm² may be provided herein.

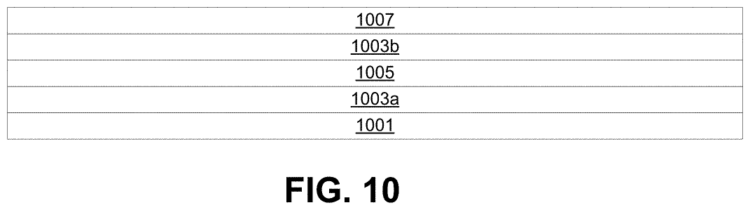

To vacuum laminate, solar cells are placed on a release layer sheet, on top of a hard substrate (such as G-11 board), solar side facing upwards. Then, they are covered with another release layer sheet and a compliant sheet. The stack undergoes a lamination process. The compliant sheet transmits pressure during lamination in such a way that tenting around the wire is reduced, more so than if the top of the stack were a rigid layer. Because of the release layer in the stack, after the lamination process, the cells are still separated from each other and from the material that comes in touch with them during lamination. FIG. 10 shows an example of a lamination stack for a vacuum lamination apparatus including a hard substrate 1001, a first release layer 1003a, a solar cell stack 1005, a second release layer 1003b, and a complaint sheet 1007. Materials and thicknesses for the compliant sheet and release layers may be the same as given above for the compliant sleeve (or belt) and release layer of the inline lamination apparatus.

Although the foregoing invention has been described in some detail for purposes of clarity of understanding, it will be apparent that certain changes and modifications may be practiced within the scope of the invention. It should be noted that there are many alternative ways of implementing both the processes and apparatuses of the present invention. Accordingly, the present embodiments are to be considered as illustrative and not restrictive, and the invention is not to be limited to the details given herein.

1. A lamination apparatus for laminating a lamination stack comprising:
a roller comprising a core and a compliant material surrounding the core, the compliant material characterized by having a pressure to compress 25% of between 1 and 30 psi; and
a release layer configured to directly contact the lamination stack.

2. The lamination apparatus of claim 1, wherein the compliant material comprises silicone.

3. The lamination apparatus of claim 1, wherein the release layer comprises woven fiberglass.

4. The lamination apparatus of claim 3, wherein the fiberglass is coated with a fluoropolymer.

5. The lamination apparatus of claim 1, wherein the thickness of the compliant material is between 0.4 mm and 40 mm.

6. The lamination apparatus of claim 1, wherein the thickness of the release layer is between 0.08 mm and 0.4 mm.

7. The lamination apparatus of claim 1, wherein the compliant material is a sleeve that annularly surrounds the core and the release layer annularly surrounds the sleeve.

8. The lamination apparatus of claim 1, wherein the release layer is in the form of a belt.

9. The lamination apparatus of claim 1, wherein the compliant material is a sleeve that annularly surrounds the core.

10. The lamination apparatus of claim 1, wherein the compliant material is in the form of a belt.

11. The lamination apparatus of claim 1, further comprising a hot air jet configured to heat part of the lamination stack before it reaches the roller.

12. A solar cell manufacturing line comprising:
a thin film web coating station to deposit thin film materials on a substrate;
one or more cutting stations to cut the substrate to form cells; a laminating apparatus as in claim 1 to form laminated solar cells; and a solar cell testing station to measure cell efficiency of the laminated solar cells.

13. A method of laminating a solar cell, comprising:
providing a lamination apparatus comprising a first roller and a second roller, the first roller comprising a core and a compliant sleeve annularly surrounding the core;
feeding a lamination stack including thin film solar cell and a wire assembly in between the first roller and the second roller, the wire assembly comprising a wire and one or more polymer layers, such that the wire assembly is between the thin film solar cell and the first roller;
compressing the lamination stack between the first roller and the second roller to laminate the wire assembly to the thin film solar cell.

14. The method of claim 13, further comprising heating the wire assembly prior to feeding it in between the first roller and second roller.

15. The method of claim 13, further comprising heating the backside of the solar cell prior to feeding it in between the first roller and the second roller.

16. The method of claim 13, wherein compressing the lamination stack comprises directly contacting the wire assembly with a release layer that is in contact with the compliant sleeve.

17. The method of claim 16, wherein the release layer annularly surrounds the compliant sleeve.

18. The method of claim 16, wherein the release layer is configured as a belt.

19. The method of claim 16, further comprising transferring a texture of the release layer to the wire assembly.

20. The method of claim 13, wherein the solar cell is a CIGS solar cell.

21.-23. (canceled)
